(19) United States
(12) Patent Application Publication
(10) Pub. No.: US 2018/0329294 A1
(43) Pub. Date: Nov. 15, 2018

(54) LITHOGRAPHY APPARATUS AND METHOD OF MANUFACTURING ARTICLE

(71) Applicant: CANON KABUSHIKI KAISHA, Tokyo (JP)

(72) Inventor: Takuro Tsujikawa, Utsunomiya-shi (JP)

(21) Appl. No.: 15/976,216

(22) Filed: May 10, 2018

(30) Foreign Application Priority Data
May 15, 2017 (JP) 2017-096540

(51) Int. Cl. G03F 7/00; G03F 7/20; G03F 9/00

(52) U.S. Cl. CPC G03F 7/0002; G03F 7/70733; G03F 7/70725; G03F 9/7084; G03F 7/70775; G03F 9/7042; G03F 9/7046; G03F 7/70683

(57) ABSTRACT

A lithography apparatus, before performing patterning, performs a first process for obtaining a position of a mark on a substrate by first template matching, and while performing patterning based on the position of the mark obtained by the first process, performs a second process for obtaining a position of the mark by second template matching different to the first template matching, performs a third process for performing a change of a template used in the first template matching by the first process based on position of mark obtained by the second process to obtain a template to be used in the first template matching by the first process.

### BACKGROUND OF THE INVENTION

### Field of the Invention

The present invention relates to a lithography apparatus and a method of manufacturing an article.

### Description of the Related Art

In a lithography apparatus for transferring a pattern of a mask to a substrate to form the pattern on the substrate, alignment of the mask and the substrate is necessary. Alignment typically includes measurement of the position of a mark formed on the substrate, and this measurement can be performed in accordance with a pattern matching process that uses a template (template matching).

Because the appearance of the shape of a mark can change in accordance with a process of the substrate, appropriate adjustment of the template is necessary in order to maintain measurement accuracy. Japanese Patent Laid-Open No. 2012-69003 discloses a method for generating a template and a search test image, using these to perform a search to obtain reference values regarding a takt time and accuracy, adjusting the template based on these reference values, and optimizing the takt time and accuracy.

The method disclosed in Japanese Patent Laid-Open No. 2012-69003 performs the same template matching in a case of obtaining reference values and a case of adjusting a template. Accordingly, appropriate reference values are not obtained if processing is performed on an image for which a measurement error due to the template matching has occurred. For template matching, because a calculation amount typically increases as the accuracy increases, when such template matching is used, it becomes difficult to satisfy restrictions on cost or throughput.

### SUMMARY OF THE INVENTION

The present invention provides, for example, a lithography apparatus advantageous for achieving both accuracy of a mark position measurement, and a cost or throughput.

The present invention in its one aspect provides a lithography apparatus operable to perform patterning on a substrate, the apparatus comprising a stage configured to be movable while holding the substrate on which a mark is formed, an imaging device configured to image the mark formed on the substrate held by the stage to obtain an image of the mark, a processor configured to process the image to obtain a position of the mark, and a patterning device configured to perform the patterning on the substrate held by the stage that is moved based on the position of the mark obtained by the processor, wherein the processor performs, based on the position of the mark obtained by a first process for obtaining a position of the mark by first template matching, a second process for obtaining a position of the mark by second template matching having a higher accuracy for obtaining a position of the mark than by the first template matching, and performs, based on the position of the mark obtained in the second process, a third process for performing a change of a template used in the first template matching in the first process to obtain a template to be used in the first template matching by the first process.

Further features of the present invention will become apparent from the following description of exemplary embodiments (with reference to the attached drawings).

### BRIEF DESCRIPTION OF THE DRAWINGS

FIG. 1 is a view for illustrating a configuration of an exposure apparatus.

FIG. 2 is a view for illustrating a configuration of a substrate.

FIG. 3 is a flowchart for illustrating a control flow for a substrate process.

FIG. 4 is a flowchart for illustrating a process for obtaining a reference measurement value.

FIG. 5 is a flowchart for illustrating a process for obtaining an alignment measurement condition.

FIG. 6 is a view for illustrating a process for determining an arrangement of a template.

FIG. 7 is a flowchart for illustrating a variation of the process for obtaining a reference measurement value.

FIG. 8 is a view for illustrating a process for determining an arrangement of a template.

FIG. 9 is a view for describing processing for searching for a mark in accordance with template matching.

FIG. 10 is a flowchart for illustrating a variation of a process for obtaining an alignment measurement condition.

### DESCRIPTION OF THE EMBODIMENTS

Various exemplary embodiments, features, and aspects of the invention will be described in detail below with reference to the drawings.

Below, description is given in detail for embodiments of the present invention with reference to the drawings. Note that the following embodiments merely illustrate concrete examples of implementing the present invention, and the present invention is not limited to the following embodiments. In addition, not all combinations of characteristic features described in the following embodiments are essential to solve the problems in the present invention.

### First Embodiment

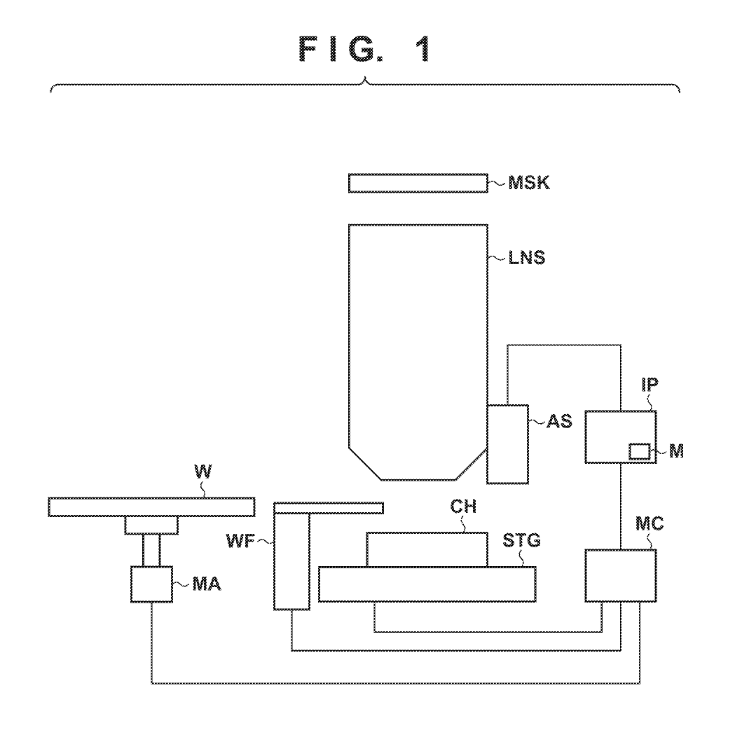

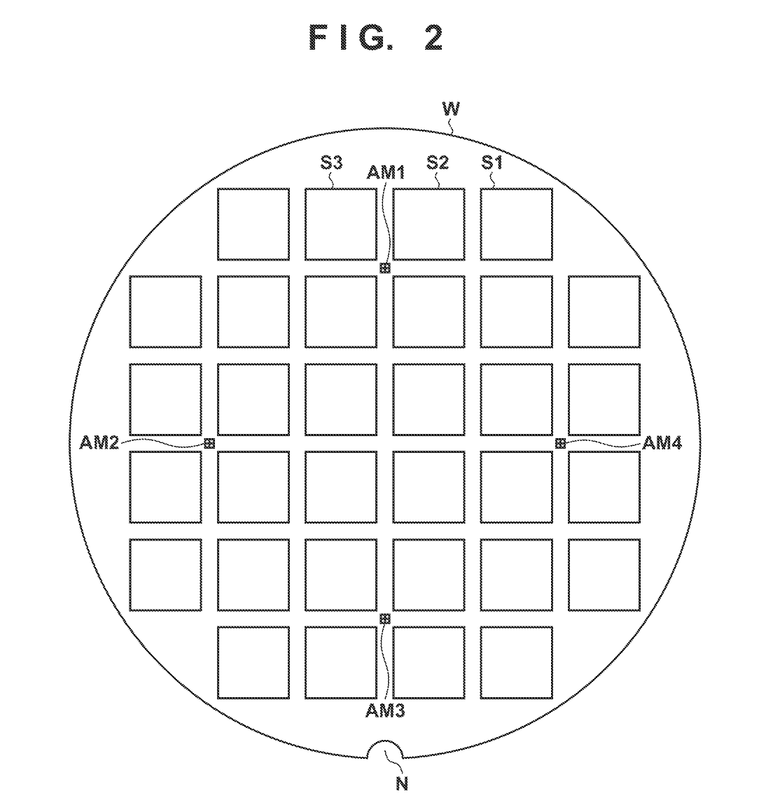

FIG. 1 is a view that illustrates a configuration of an exposure apparatus that is an example of a lithography apparatus, according to an embodiment, for forming a pattern on a substrate. FIG. 2 is a view that illustrates a configuration of a substrate W that is processed by the exposure apparatus of FIG. 1. In FIG. 2, a plurality of shot regions including S1, S2 and S3 are formed in the substrate W, and marks AM1, AM2, AM3 and AM 4 (alignment marks) are formed at predetermined positions on the substrate W. Furthermore, a notch N which is a cutout is formed in a portion of a peripheral portion of the substrate W. In FIG. 1, a substrate conveyance unit WF conveys the substrate W into the apparatus. A mechanical pre-alignment unit MA detects the notch N in the substrate W, and performs pre-alignment to adjust at least one of the position and rotation angle of the substrate W. A substrate stage STG is a moveable stage for holding the substrate W. A chuck CH for holding the substrate W is installed on the substrate stage STG. An alignment scope AS includes an imaging device for imaging the marks AM1 through AM4 on the substrate W to obtain images of the marks. A processor IP performs mark position measurement in accordance with template matching, for example, based on the images obtained by the alignment scope AS. In addition to a CPU (not shown), the processor IP can include a memory M for storing various data or the like. A controller MC operates as a patterning device for forming a pattern on the substrate W that is held on the substrate stage STG which is moved based on the positions of the marks obtained by the processor IP. Specifically, the controller MC forms the pattern on the substrate W by causing the substrate stage STG to move based on position measurement information from the processor IP to perform alignment of the substrate W, and then performing an exposure process for exposing a pattern of the mask MSK onto the substrate W through an exposure lens LNS.

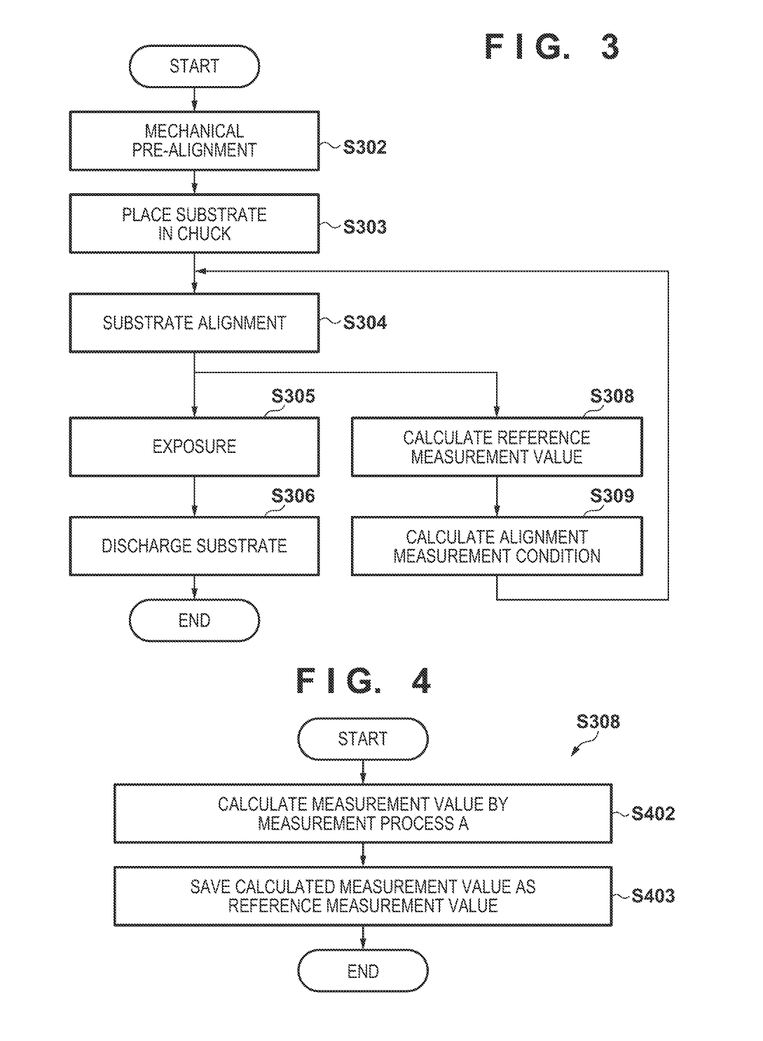

FIG. 3 illustrates a control flow for a substrate process performed by the controller MC. In step S302, the controller MC controls the mechanical pre-alignment unit MA to perform mechanical pre-alignment with respect to the substrate W which has been conveyed to within the apparatus by the substrate conveyance unit WF. In step S303, the controller MC controls the substrate conveyance unit WF to convey the substrate W to the chuck CH. In step S304, the controller MC, before operating as a patterning device, causes the processor IP to perform a first process for obtaining positions of marks in accordance with first template matching. Subsequently, the controller MC performs substrate alignment by causing the substrate stage STG to move based on positions of the marks obtained by the first process. The first template matching obtains the positions of marks by using a template that represents an ideal shape of a mark by a plurality of discrete feature points to search for the positions of the marks in an image obtained by the alignment scope AS.

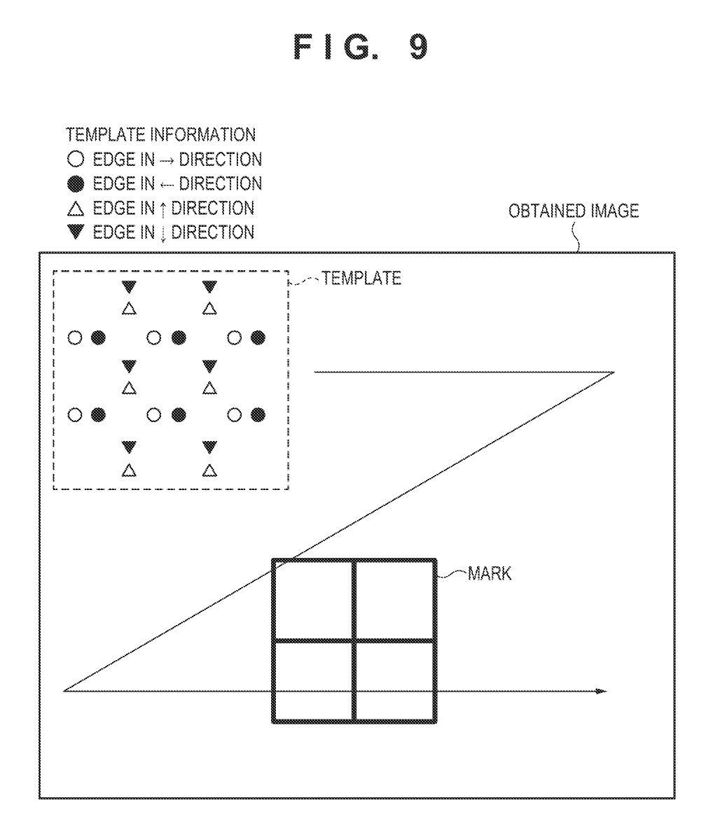

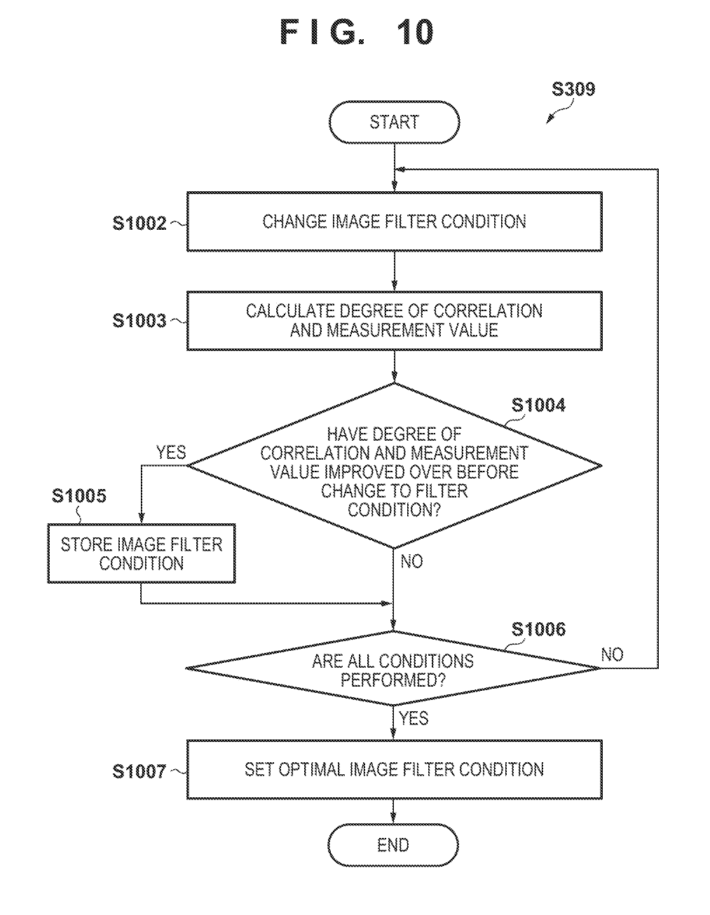

Arrangement of the template and the number of feature points in the template (the number of points of the template) are examples of measurement conditions (alignment measurement conditions) in the first template matching. For example, a search for marks in an image obtained for measurement, as illustrated in FIG. 9, is performed by using a template having information of edge directions of a mark AM as with reference numeral 8a of FIG. 8. Specifically, a position having a maximum degree of correlation (similarity) is searched for, and that position is determined as the measurement value. Note that it is assumed that, if the substrate that is the target of processing is the first of a lot, the alignment measurement condition uses a default condition or a condition set in a previous lot.

After performing the substrate alignment, the controller MC performs exposure for each substrate W shot region (step S305). After the completion of exposure, the controller MC controls the substrate conveyance unit WF to discharge the substrate W (step S306).

The substrate processing in the present embodiment is generally as above. However, because the appearance of the shape of a mark can change in accordance with a process of the substrate, appropriate adjustment of the template is necessary in order to maintain accuracy of position measurement. Accordingly, in the present embodiment, the controller MC, in parallel with the exposing in step S305 and the discharge of the substrate in step S306 (in other words, while the patterning device is performing the foregoing operations), executes template adjustment operations of step S308 and step S309. Step S308 is a second process for obtaining the positions of marks by second template matching that is different to the first template matching. Step S309 is a third process for performing changes, based on the positions of the marks obtained in the second process, of the template used in the first template matching in the first process to obtain a template to be used in the first template matching by the first process.

The second process of step S308 can include processing for calculating a reference measurement value for indicating the position of a mark. A flow for the calculation of this reference measurement value is illustrated in FIG. 4. The flow of FIG. 4 can be executed by the processor IP under the control of the controller MC. The processor IP uses an image of the marks processed by the substrate alignment step (step S304) that is obtained by the alignment scope AS to calculate a measurement value in accordance with a measurement process A (step S402). Subsequently, the processor IP stores the calculated measurement value in the memory M as a reference measurement value (step S403). The measurement process A includes the second template matching which has a larger calculation amount than the first template matching that is used in the substrate alignment step (step S304) but can obtain the positions of marks with higher accuracy. It is possible to employ a phase restricting correlation method or a Lukas-Kanade method, for example, for the method of the second template matching in the measurement process A. The phase restricting correlation method is a method in which high detection accuracy is obtained even with a low-contrast image, by focusing on an amount of deviation of a phase instead of an amplitude of luminance. However, the calculation amount is high because a source image and a measurement image are subject to FFTs to perform a phase comparison for the entire surface of the images. In addition, for the Lukas-Kanade method, mutual information of images is used as a feature amount. In the Lukas-Kanade method, a movement amount of a respective pixel in the two images is detected by using a polynomial approximation in accordance with a Taylor expansion, and although high accuracy detection is possible as accuracy of the approximation increases as the number of polynomials increases, a large calculation amount is still required. With either method there is high robustness, and it is possible to perform position detection with higher accuracy because the amount of information used in measurement is larger than template matching that obtains a degree of correlation with discrete template information (the first template matching).

The third process of step S309 can include processing for calculating an alignment measurement condition. Here, with a default condition or a condition determined at a time of substrate processing for a previous lot as an initial state, an alignment measurement condition with respect to the image obtained beforehand in the substrate alignment step (step S304) is calculated.

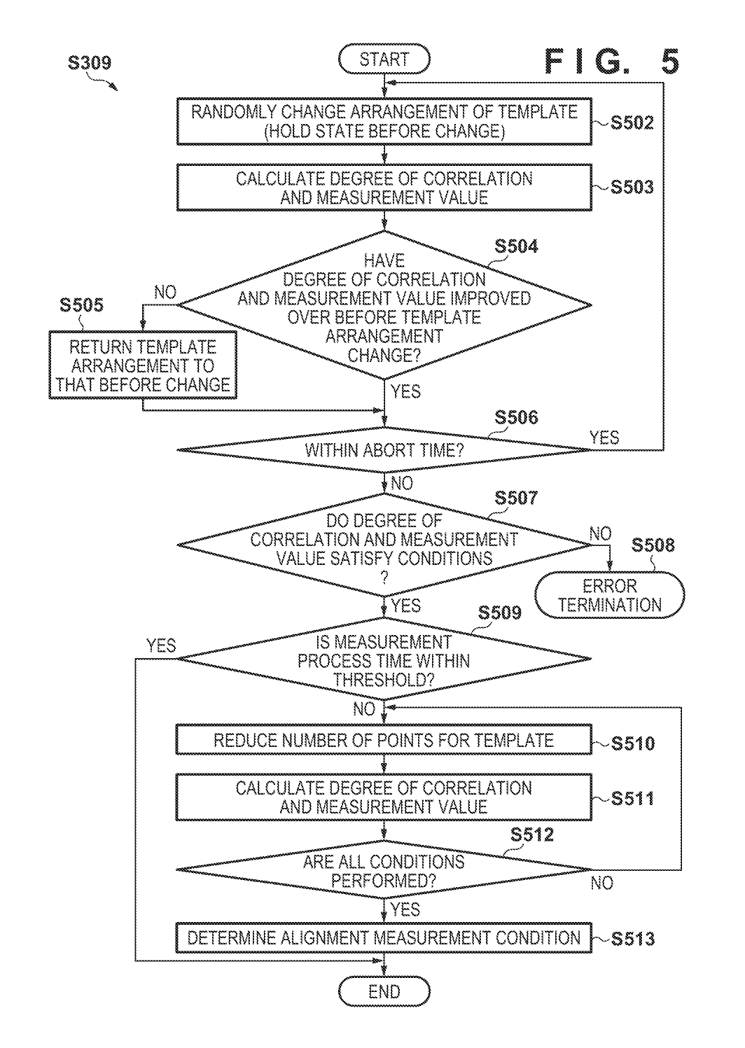

A flow for processing for calculating (step S309) the alignment measurement condition in the third process is illustrated in FIG. 5. The template information held in the initial state in this process corresponds to a mark design value (an ideal mark shape) (the template 8a of FIG. 8). The template holds information of edge directions of marks, and represents discrete mark shapes. In some processes, there are for example cases where marks are distorted, such as where a mark appears elongated in only a horizontal direction (a template 8b of FIG. 8). In such a case, there is a difference between a template and the mark, and a calculated degree of correlation will be lower than in an ideal state. Accordingly, as the third process, the processor IP determines the arrangement of the template (changes the template) so that the positions of the marks obtained by the first process (step S304) approaches the positions of the marks obtained by the second process (step S308) as illustrated in detail below.

Step S502 through step S508 of FIG. 5 is an arrangement determination process for determining the arrangement of a template by repeating the first template matching while changing the arrangement of the template. Firstly, the processor IP, in step S502, randomly changes the arrangement of the template from the initial state, and, in step S503, performs the first template matching (calculates a degree of correlation and a measurement value) in accordance with the changed template. Next, in step S504, the processor IP determines whether the degree of correlation and the measurement value have improved in comparison to before the change to the arrangement of the template. Here, “the degree of correlation and the measurement value improve” means the degree of correlation increases and the measurement value approaches the reference measurement value. Specifically, “the degree of correlation and the measurement value improve” means the degree of correlation between a mark and the template exceeds a predetermined threshold, and the measurement value which indicates the position of the mark falls within a predetermined threshold range that includes the reference measurement value obtained in step S308. For example, with the template 8c of FIG. 8, one point of the template is randomly selected and moved in a leftward direction. In this case, because the point goes in a direction away from the mark, the degree of correlation and the measurement value do not improve (NO in step S504). Accordingly, the processor IP returns the template arrangement to the arrangement before the change was made in step S502 (the template 8b of FIG. 8) (step S505).

In step S506, the processor IP determines whether an amount of time that has elapsed from the start of processing for step S309 is within a predetermined abort time, based on the amount of time incurred for the patterning operation. In a case where the elapsed time is within the predetermined abort time (YES in step S506), one point of the template is randomly selected again and arrangement thereof is moved. As an example, with the template 8d of FIG. 8, the point of the template selected in the template 8c of FIG. 8 is selected again, and moved in a rightward direction, in other words in a direction nearer a mark. In this case, because the degree of correlation with respect to the mark increases and the degree of correlation for portions other than the mark decrease, the template arrangement is held in the state of the template 8d of FIG. 8 (step S504).

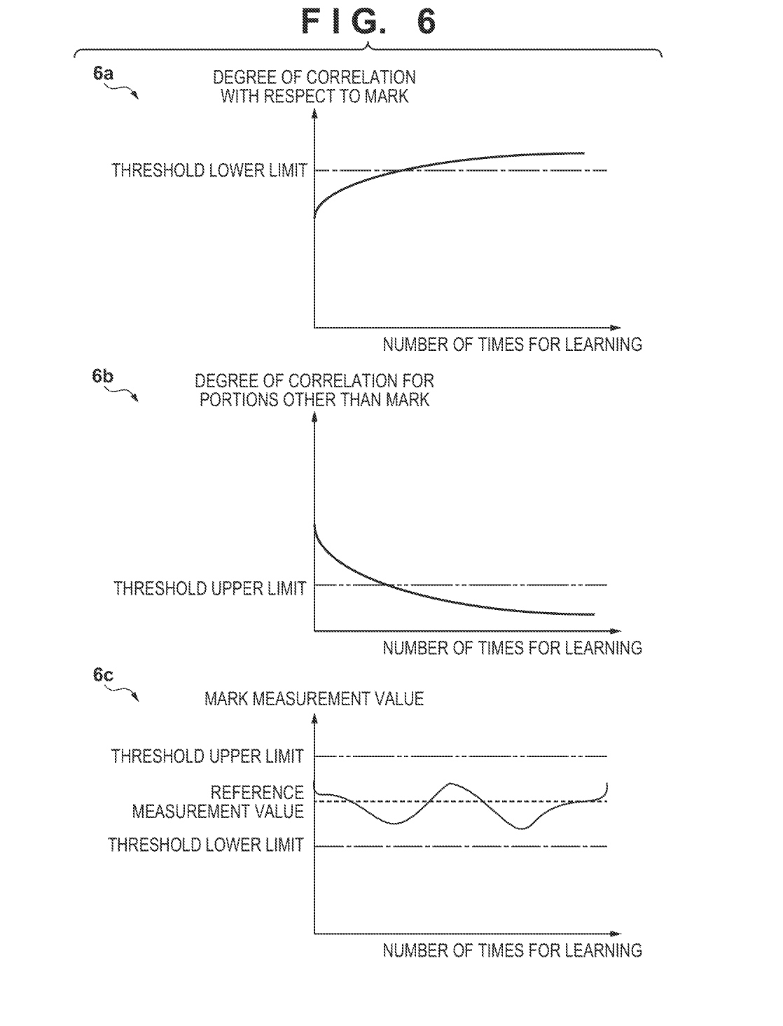

By repeating step S502 through step S506 within the predetermined abort time to increase a number of times for learning, as illustrated by a graph 6a of FIG. 6, the degree of correlation with respect to the mark increases, and as illustrated by a graph 6b of FIG. 6, a degree of correlation for portions other than the mark decreases. In addition, as illustrated by a graph 6c of FIG. 6, the measurement value for the mark converges between a predetermined threshold upper limit and threshold lower limit that are defined in accordance with the reference measurement value. When the elapsed time exceeds the predetermined abort time (NO in step S506), the processor IP, in step S507, determines whether the following conditions regarding the degree of correlation and the measurement value are satisfied, for example.
That the degree of correlation with respect to a mark in accordance with a final template arrangement exceeds the predetermined threshold lower limit (the graph 6a of FIG. 6).
That the degree of correlation with respect to portions other than the mark in accordance with a final template arrangement falls below the predetermined threshold upper limit (the graph 6b of FIG. 6).
That the measurement value in accordance with the final template arrangement is within the predetermined threshold range that is defined in accordance with the reference measurement value calculated in step S308 (the graph 6c of FIG. 6).

In this way, the third process performs changes to the template so that the degree of correlation between a mark and the template exceeds a threshold, and deviation from the position of the mark obtained by the second process to the position of the mark obtained by the first process falls within an allowable range. In addition, the processor IP aborts the third process based on an amount of time required for the patterning operation.

When the foregoing conditions are not satisfied, error termination occurs (step S508). In other words, the processor IP outputs information indicating an error relating to the first process, for example, if the degree of correlation does not exceed the threshold or the deviation does not fall within the allowable range by when the third process is aborted. The template arrangement is determined by the processing thus far (a template 8e of FIG. 8). In a case where the foregoing conditions are satisfied, in step S509, a determination is made as to whether the amount of time that has elapsed since the start of processing for the first measurement process in step S304 is within a predetermined threshold. When the amount of time that has elapsed is within the predetermined threshold or if restriction on processing time is not caused to be held (YES in step S509), processing for calculating an alignment measurement condition ends at this point in time. The alignment measurement condition of this point is used in a substrate alignment process (step S304) which is a first measurement process with respect to a subsequent substrate. Consequently, it is possible to find a template shape for which measurement processing time and measurement accuracy with respect to a mark of a substrate that is a target are optimal, without influencing apparatus throughput.

If the restriction of the measurement processing time of the first measurement process is not satisfied in step S509 (NO in step S509), a learning loop for determining a number of points for an optimal template is stepped through (step S510 through step S512). This processing is point-number determination processing in which the first template matching is repeated while reducing the number of feature points of the template having the determined arrangement, and a minimum number of points is determined under a condition that the degree of correlation of the mark exceeds the predetermined threshold and the measurement value is within the predetermined threshold range. Specifically, the processor IP, in step S510, reduces the number of points of the template by 1, and, in step S511, calculates the degree of correlation and the measurement value by the same method as in the first measurement process for the template after this change. In step S512, it is determined whether all conditions are met, in other words whether the number of points for the template has reached a predetermined lower limit value. Here, if the number of points for the template has not reached the predetermined lower limit value, the processing returns to step S510, and when the predetermined lower limit value is reached the processing advances to step S513. In this way, the number of points for the template is caused to decrease, and the minimum number of points for the template in order to satisfy the foregoing conditions relating to the degree of correlation and the measurement value is determined as the alignment measurement condition (step S513). The obtained template measurement condition is used as a measurement condition for a substrate alignment which is the first measurement process (step S304) for the subsequent substrate. Consequently, it is possible to find a template shape for which measurement processing time and measurement accuracy with respect to a mark of a substrate that is a target are optimal.

In FIG. 5, the shape of the template is optimized as the third process, but optimization of a different parameter may be performed. For example, configuration may be taken such that, in step S309, a plurality of image filter conditions are attempted with respect to a measurement image, and one for which a measurement value is optimal is selected. A processing flow for such a step S309 is illustrated in FIG. 10. Here, an initial condition for an image filter condition is sigma=0.10 for a Gaussian filter, for example. The processor IP firstly, in step S1002, changes the image filter condition from the initial condition. Here, sigma for the image filter is set in order in 0.01 increments from 0.10 to 0.99, for example. In step S1003, the processor IP calculates the degree of correlation and the measurement value in accordance with the first measurement process by the image filter condition after the change. If the calculated degree of correlation and measurement value have improved over before the filter condition change (YES in step S1004), the image filter condition for this point is stored in the memory M (step S1005) and subsequently the processing proceeds to step S1006. If the calculated degree of correlation and measurement value have not improved over before the filter condition changes (NO in step S1004), the processing proceeds to step S1006 in the present state. In step S1006, the processor IP determines whether all image filter conditions have been performed, in other words whether measurement has been performed for all values of 0.10 through 0.99 for sigma of the image filter. If measurement by all image filter conditions has not been performed the processing returns to step S1002, and when measurement by all image filter conditions has been performed the processing proceeds to step S1007.

In step S1007, the processor IP sets the filter condition for which the degree of correlation and the measurement value increased the most as the image filter condition for the first measurement process. Consequently, even if there is a change in the appearance of the substrate, it is possible to always select an optimal filter condition. Note that, although sigma of a Gaussian filter is optimized as an image filter condition in this example, a parameter for another image filter (such as a median filter or a Gabor filter) or a condition for combining filters with each other may be optimized.

(First Variation)

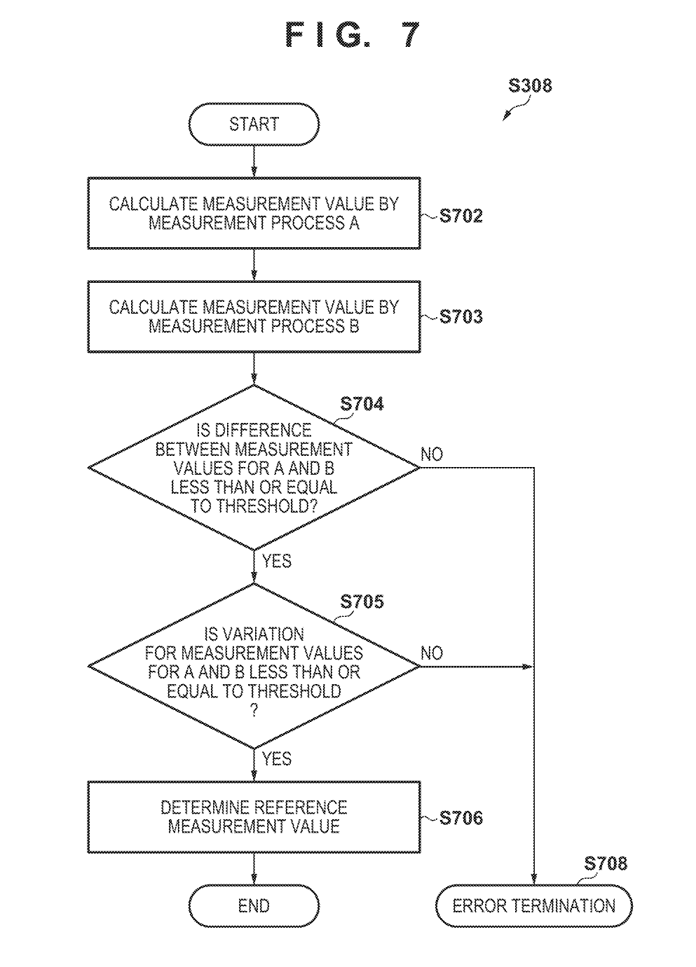

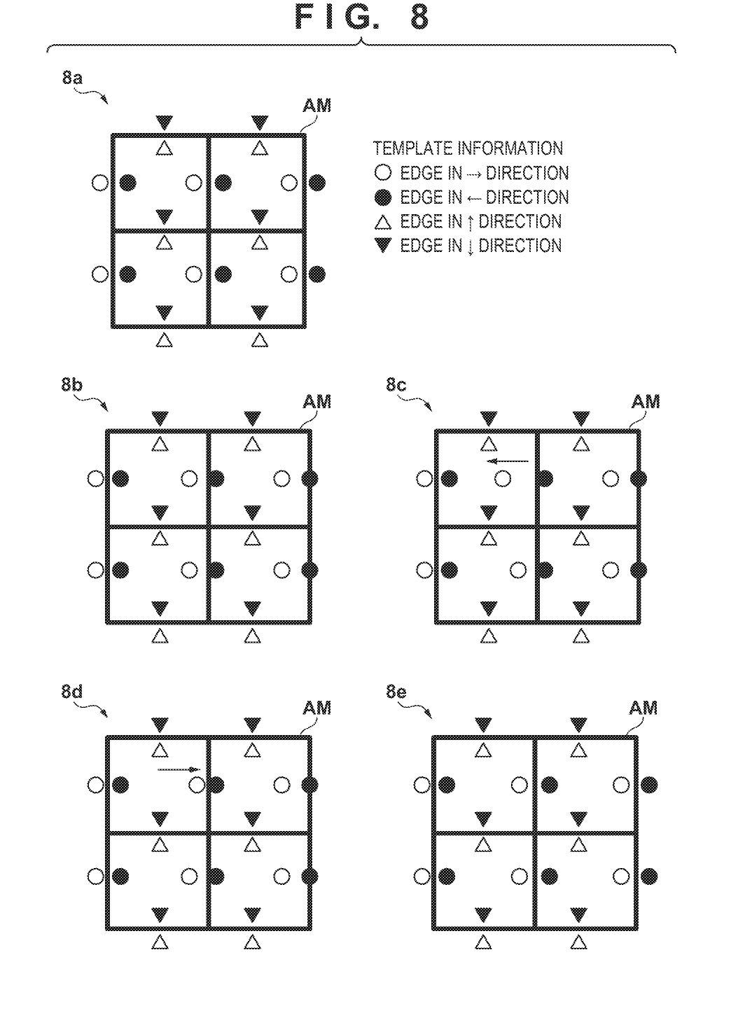

A variation of processing for calculating (step S308) the reference measurement value which is the second process is illustrated in FIG. 7. In the example of FIG. 4, the measurement process A which can perform high accuracy measurement by a larger calculation amount than the first measurement process is used, but here a plurality of measurement processes including a measurement process B in addition to the measurement process A is used as measurement processes for performing high accuracy measurement. In other words, the second template matching can include a plurality of template matching having different search methods. For example, the measurement process A can be a measurement process that uses a phase restricting correlation method, and the measurement process B can be a measurement process that uses the Lukas-Kanade method.

The controller MC, in step S702, calculates a measurement value by the measurement process A, and, in step S703, calculates a measurement value by the measurement process B. Subsequently, the controller MC determines whether a difference between the measurement value obtained in step S702 and the measurement value obtained in step S703 is less than or equal to a predetermined threshold (step S704), and whether variation between the measurement value obtained in step S702 and the measurement value obtained in step S703 is less than or equal to a predetermined range (step S705). If these conditions are not met, it is determined that an abnormality has occurred in the measurement, and an error is outputted (step S708). If these conditions are satisfied, for example an average of the measurement value obtained in step S702 and the measurement value obtained in step S703 is determined as the reference measurement value (step S706). In this way, in the second process, information indicating an error relating to the second process is output in a case where variation of positions of a plurality of marks respectively obtained in accordance with a plurality of template matching does not fall within an allowable range.

By the above processing, it is possible to improve the reliability of a reference value by combining both measurement results, because the measurement process A and the measurement process B perform measurements with respect to the same image that use different characteristics. Consequently, it is possible to calculate a reference measurement value having higher accuracy.

(Second Variation)

By the substrate process described above, the mark image obtained by the substrate alignment step (step S304) is used in the calculation of the reference measurement value (step S308) which is the second process, and in the calculation of the alignment measurement condition (step S309). As a variation, the controller MC may store, in a memory, a mark image for substrates in the same lot that were processed up until the previous time. The controller MC then performs the calculation of the reference measurement value (step S308) and the calculation of the alignment measurement condition (step S309) with respect to each of a plurality of mark images stored in the memory to find a measurement condition for which the measurement accuracy and the processing time are optimal for all mark images. Consequently, it is possible to find an alignment measurement condition for a substrate that is most suitable for process fluctuation in a lot of substrates.

<Embodiment of Method of Manufacturing Article>

A method of manufacturing an article according to an embodiment of the present invention is suitable to manufacturing an article such as an element having a microstructure or micro-device such as a semiconductor device, for example. The method of manufacturing an article of the present embodiment includes a step for using the foregoing lithography apparatus (an exposure apparatus, an imprint apparatus, drawing apparatus, or the like) to transfer a pattern of a mask to a substrate, and a step for processing the substrate to which the pattern was transferred in the corresponding step. Furthermore, the corresponding manufacturing method includes other well-known steps (such as oxidation, film formation, vapor deposition, doping, planarization, etching, resist stripping, dicing, bonding, and packaging). The method of manufacturing an article of the present embodiment is advantageous in at least one of capability, quality, productivity, and manufacturing cost of the article in comparison to a conventional method.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2017-096540, filed May 15, 2017, which is hereby incorporated by reference herein in its entirety.

What is claimed is:

1. A lithography apparatus operable to perform patterning on a substrate, the apparatus comprising:
a stage configured to be movable while holding the substrate on which a mark is formed;
an imaging device configured to image the mark formed on the substrate held by the stage to obtain an image of the mark;
a processor configured to process the image to obtain a position of the mark; and
a patterning device configured to perform the patterning on the substrate held by the stage that is moved based on the position of the mark obtained by the processor,
wherein the processor
performs, based on the position of the mark obtained by a first process for obtaining a position of the mark by first template matching, a second process for obtaining a position of the mark by second template matching having a higher accuracy for obtaining a position of the mark than by the first template matching, and
performs, based on the position of the mark obtained in the second process, a third process for performing a change of a template used in the first template matching in the first process to obtain a template to be used in the first template matching by the first process.

2. The lithography apparatus according to claim 1, wherein the processor, in the second process, obtains the position of the mark while the patterning device is performing the patterning.

3. The lithography apparatus according to claim 1, wherein the processor, in the third process, performs the change so that the position of the mark obtained by the first process approaches the position of the mark obtained by the second process.

4. The lithography apparatus according to claim 3, wherein the processor, in the third process, performs the change so that a degree of correlation between the mark and the template exceeds a threshold, and deviation from the position of the mark obtained by the second process to the position of the mark obtained by the first process falls within an allowable range.

5. The lithography apparatus according to claim 4, wherein the processor aborts the third process based on an amount of time required for the patterning.

6. The lithography apparatus according to claim 5, wherein, in response that the degree of correlation does not exceed the threshold or the deviation does not fall within the allowable range before aborting the third process, the processor outputs information indicating an error in relation to the first process.

7. The lithography apparatus according to claim 1, wherein the processor, in the third process, changes a number of feature points for configuring the template.

8. The lithography apparatus according to claim 1, wherein the second template matching includes a plurality of template matchings that are mutually different, and the second process obtains, as the position of the mark, an average of a plurality of positions of the mark respectively obtained by the plurality of template matchings.

9. The lithography apparatus according to claim 8, wherein the processor, in the second process, outputs information indicating an error in relation to the second process in response that variation of the plurality of positions of the mark respectively obtained by the plurality of template matchings does not fall within an allowable range.

10. A method for manufacturing an article, the method comprising:
moving a stage that holds a substrate based on a position of a mark formed on the substrate, and performing patterning on the substrate that is held by the stage by using a lithography apparatus according; and
performing processing of the substrate on which the pattern has been formed,
wherein the article is manufactured from the substrate on which the processing is performed,
wherein the lithography apparatus is operable to perform patterning on the substrate, the lithography apparatus comprises:
a stage configured to be movable while holding the substrate on which a mark is formed;
an imaging device configured to image the mark formed on the substrate held by the stage to obtain an image of the mark;
a processor configured to process the image to obtain a position of the mark; and
a patterning device configured to perform the patterning on the substrate held by the stage that is moved based on the position of the mark obtained by the processor,
wherein the processor
performs, based on the position of the mark obtained by a first process for obtaining a position of the mark by first template matching, a second process for obtaining a position of the mark by second template matching having a higher accuracy for obtaining a position of the mark than by the first template matching, and
performs, based on the position of the mark obtained in the second process, a third process for performing a change of a template used in the first template matching in the first process to obtain a template to be used in the first template matching by the first process.
